(19) United States
(12) Patent Application Publication
(10) Pub. No.: US 2024/0369625 A1
(43) Pub. Date: Nov. 7, 2024

(54) METHOD FOR SEPARATING AND MODELING N-UI JITTER BASED ON SPECTRUM

(71) Applicant: Tektronix, Inc., Beaverton, OR (US)

(72) Inventor: Mark L. Guenther, Portland, OR (US)

(21) Appl. No.: 18/654,577

(22) Filed: May 3, 2024

Related U.S. Application Data
(60) Provisional application No. 63/464,517, filed on May 5, 2023.

(51) Int. Cl. G01R 31/317

(52) U.S. Cl. CPC G01R 31/31709

(57) ABSTRACT

A method and system of separating and determining components total jitter for a signal under test includes determining a time interval error (TIE) spectrum for the signal under test. The TIE spectrum includes a plurality of frequency bins. The method identifies frequency bins in the TIE spectrum containing deterministic jitter. The method includes determining components of total jitter for the signal under test based on frequency bins in an N-UI spectrum for the signal under test corresponding to the identified frequency bins in the TIE spectrum.

### CROSS-REFERENCE TO RELATED APPLICATIONS

This disclosure is a non-provisional of and claims benefit from U.S. Provisional Application No. 63/464,517, titled “METHOD FOR SEPARATING AND MODELING N-UI JITTER BASED ON SPECTRUM,” filed on May 5, 2023, the disclosure of which is incorporated herein by reference in its entirety.

### TECHNICAL FIELD

This disclosure relates generally to measurement of jitter in a signal under test, and more particularly to measuring components of N-period jitter (i.e., N-UI jitter) in a signal under test with a test and measurement instrument such as an oscilloscope.

### BACKGROUND

Jitter of an electrical signal is deviation in timing of the signal from an ideal timing and results in improper positioning of edges of the signal from their ideal positions. Jitter comes in several different forms depending on how it is measured, such as TIE-based jitter or N-Period-based jitter. N-Period-based jitter, or simply N-Period jitter, may also be called N-UI-based jitter, and these terms are synonymous throughout the following discussion. Within each form, jitter can be broadly categorized into deterministic (DJ) and random jitter (RJ). Random jitter (RJ) has no distinct amplitude bound and is assumed to be Gaussian in nature. In contrast, deterministic jitter (DJ) is not random and is bounded in amplitude. Deterministic Jitter (DJ) includes Data Dependent Jitter (DDJ), Duty Cycle Distortion (DCD), and Periodic Jitter (PJ). Data Dependent Jitter DDJ is also known in the art as Intersymbol Interference (ISI). Total Jitter (TJ) is a direct or indirect measurement of the actual or predicted sum of all the independent jitter components, at a specified statistical probability (i.e., the Bit Error Rate, or BER). Thus, total jitter TJ is often designated as TJ@BER. Jitter may be present in clock signals as well as serial data signals, and may cause errors in the communication of signals in serial communication systems. As a result, determining the amount and type of jitter present in a signal is desirable when testing serial communication systems or components thereof.

To perform testing of a serial communication system, a test and measurement instrument, such as an oscilloscope, is typically used. The test and measurement instrument acquires a waveform of a signal being tested or a “signal under test” and then jitter can be measured from the acquired waveform. Jitter may be characterized using different metrics, such as through a time interval error (TIE) time train for the signal under test or an N unit interval (UI) or “N-UI” time train for the signal under test, and for a given metric, values such as random jitter RJ or total jitter TJ at a BER of 1e-12 (TJ@ 1e-12) may be calculated. Whether total jitter TJ is measured based on the TIE time train or an N-UI time train of a signal under test, there is a need for enabling a user to utilize the test and measurement instrument to determine or separate the deterministic jitter DJ, random jitter RJ and total jitter TJ components of the overall jitter of a signal under test. One technique for separating deterministic jitter DJ and random jitter RJ is a spectrum analysis-based approach in which the frequency spectrum of the TIE or N-UI time train is analyzed to perform jitter separation. Note that the random jitter RJ value based on one metric (such as TIE) will generally differ numerically from the random jitter RJ value based on a different metric (such as 10-period jitter for N-UI-based jitter), for the same signal under test. Values for deterministic jitter DJ or total jitter TJ at a BER will likewise generally differ when different jitter measurement metrics are used. There is accordingly a need for techniques, which may be implemented in test and measurement instruments, of determining random jitter RJ, deterministic jitter DJ and total jitter TJ values of a signal under test for both TIE and N-UI jitter measurement metrics.

### BRIEF DESCRIPTION OF ACCOMPANYING DRAWINGS

FIG. 1 illustrates a test and measurement system including a test and measurement instrument containing an N-UI jitter analyzer for measuring components of N-UI jitter in a signal under test in accordance with some embodiments of the disclosure.

FIG. 2 is a flowchart illustrating a process executed by the N-UI jitter analyzer of FIG. 1 in determining components of total jitter using an N-UI spectrum of a signal under test in accordance with some embodiments of the disclosure.

FIG. 3 is a frequency spectrum plot illustrating a time interval error (TIE) spectrum for a signal under test and showing components of total jitter of the signal under test and illustrating how a spectral-based approach may be utilized to separate and measure types of jitter in a signal under test.

FIGS. 4A, 4B, 4C, and 4D are frequency spectrum plots showing a TIE spectrum and showing corresponding N-UI spectrums for several different values of N and illustrating the scalloped nature of the N-UI spectrums that is material to the N-UI jitter analyzer of FIG. 1 in accordance with some embodiments of the disclosure.

### DETAILED DESCRIPTION

Embodiments of the present disclosure are directed to methods, and systems implementing these methods, of determining the N-UI-based jitter components such as random jitter RJ, deterministic jitter DJ and total jitter TJ of a signal under test. The embodiments utilize a spectrum analysis-based approach that enables the separation of random jitter RJ and deterministic jitter DJ and also allows individual components of deterministic jitter to be determined. Embodiments enable a test and measurement instrument, such as an oscilloscope, to perform jitter measurements for a signal under test using direct jitter measurements based only on the TIE jitter measurement metric, after which the corresponding N-UI jitter components may be computed mathematically. This is advantageous since it leads to higher measurement accuracy and is computationally more efficient, thereby reducing test time. In addition, some users of the test and measurement instrument may prefer either the TIE-based or N-UI-based jitter values. Moreover, in some instances the jitter measurement metric may be mandated by a standard to which the signal under test must comply, such as for signaling requirements under the relatively new Double Data Rate 5 Synchronous Dynamic Random Access Memory (DDR5 SDRAM) memory device standard.

In some embodiments, a method includes determining a time interval error (TIE) spectrum for a signal under test. The TIE spectrum includes a plurality of frequency bins and the method includes identifying frequency bins in the TIE spectrum containing deterministic jitter for the signal under test. The method then includes determining, from the TIE spectrum, an N-UI spectrum for the signal under test that includes a plurality of frequency bins. Determining the N-UI spectrum directly from the TIE spectrum eliminates the need to perform computationally intensive Fourier transform operations to generate the N-UI spectrum, which is advantageous when implementing the method in a test and measurement instrument that may have more limited computational capabilities. Finally, the method includes determining components of total jitter in the signal under test based on frequency bins in the N-UI spectrum that correspond to the identified frequency bins in the TIE spectrum. Identifying the locations or frequency bins containing deterministic jitter utilizing the TIE spectrum before analyzing the N-UI spectrum to quantify and identify different components of deterministic jitter DJ eliminates issues that arise due to the scalloped nature of N-UI spectrums relative to TIE spectrums for the signal under test, which will be discussed in more detail below.

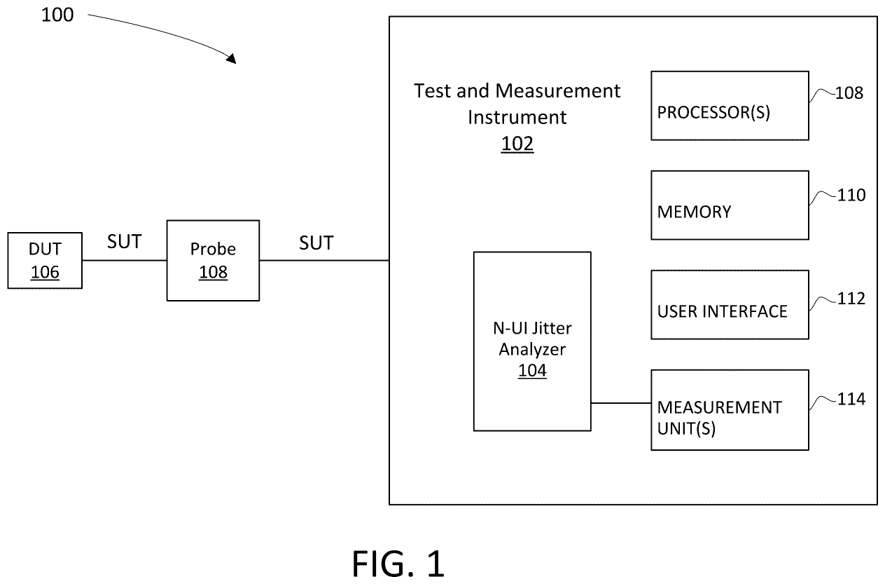

FIG. 1 illustrates a test and measurement system 100 including a test and measurement instrument 102 containing an N-UI jitter analyzer 104 for separating and measuring components of N-UI-based jitter of a signal under test SUT in accordance with some embodiments of the disclosure. In operation, the N-UI jitter analyzer 104 utilizes a TIE spectrum for the signal under test SUT to identify the location of spectral components of deterministic jitter in this spectrum. The TIE spectrum includes a plurality of frequency bins and the N-UI jitter analyzer 104 identifies the location of the spectral components of deterministic jitter DJ by identifying frequency bins containing such deterministic jitter in the TIE spectrum. The N-UI jitter analyzer 104 thereafter determines the N-UI spectrum for the signal under test SUT using the TIE spectrum. This direct determination of the N-UI spectrum from the TIE spectrum eliminates the need for the N-UI jitter analyzer 104 to perform additional Fourier transforms to obtain the N-UI spectrum, which the N-UI jitter analyzer subsequently processes to separate and measure random jitter RJ and deterministic jitter DJ components of total jitter for the signal under test SUT, as will be described in more detail below.

The test and measurement instrument 102 further includes one or more processors 108 that may be configured to execute instructions from main memory 110 and may perform any methods and/or associated steps indicated by such instructions. A user interface 112 is coupled to the one or more processors 108 and may include, for example, a keyboard, mouse, touchscreen, output display, file storage, and/or any other controls employable by a user to interact with the test and measurement instrument 102. In some embodiments the user interface 112 may be connected to or controlled by a remote interface (not illustrated) so that a user may control operation of the instrument 102 in a remote location physically away from the instrument. A display portion of the user interface 112 may be a digital screen such as a liquid crystal display (LCD), or any other monitor to display waveforms, measurements, and other data to a user. In some embodiments, the main output display of the user interface 112 may also be located remote from the instrument 102.

The test and measurement instrument 102 further includes one or more measurement units 114 that perform the functions of measuring parameters and other qualities of signals from a DUT 106 that are being measured and tested by the test and measurement instrument. Typical measurements include measuring voltage, current, and power of input signals in the time domain, as well as measuring features of the signals in the frequency domain. The measurement units 114 represent any measurements that are typically performed on test and measurement instruments, and the N-UI jitter analyzer 104, or any component thereof, may be integrated within or coupled to such measurement units 114. The DUT 106 is coupled to the test and measurement instrument 102 through a probe 108, which may also be a suitable test fixture coupling the DUT to the test and measurement instrument. The signal under test SUT from the DUT 106 is coupled through the probe 108 to the test and measurement instrument 102. The DUT 106 may be any type of electronic circuit for which jitter of a signal or signals of the DUT are to be measured or analyzed based on N-UI jitter measurements. For example, the DUT 106 may be a DDR SDRAM.

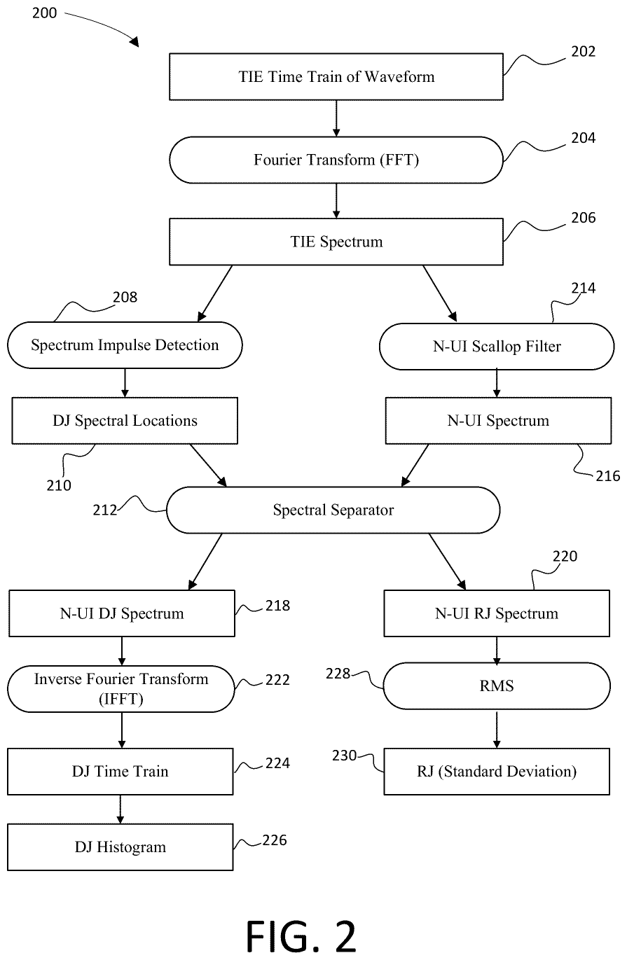

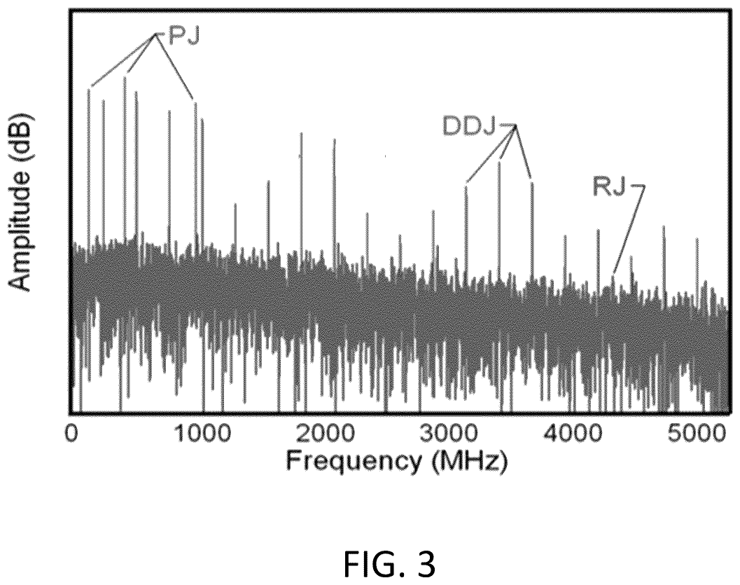

The operation of the N-UI jitter analyzer 104 will now be described in more detail with reference to FIG. 2, which is a flowchart illustrating a process 200 executed by the N-UI jitter analyzer 104 of FIG. 1 in determining components of N-UI-based jitter of a signal under test in accordance with some embodiments of the disclosure. Before describing the process 200, the spectrum analysis-based approach for measuring and separating components of total jitter on which embodiments of the disclosure are based will be first be briefly described with reference to FIG. 3. FIG. 3 is a frequency spectrum plot illustrating a time interval error (TIE) spectrum for a signal under test showing components of the overall jitter in the signal under test SUT that illustrates how a spectral-based approach may be utilized to separate and measure components of the jitter.

The separation of the random jitter RJ and deterministic jitter DJ components of total jitter of a signal under test is based on two assumptions. First, random jitter RJ is assumed to be Gaussian, meaning its spectrum is broad and distributed over all frequencies. Second, deterministic jitter DJ is comprised of one or more components, each of which are periodic in the time domain, resulting in a spectrum with corresponding spikes or impulses in the frequency domain.

FIG. 3 illustrates that random jitter RJ appears in the TIE spectrum for the signal under test SUT as a relatively constant “noise floor” in the spectrum. Frequency is shown along the horizontal axis and magnitude of frequency or spectral components shown along the vertical axis. Although not expressly shown in FIG. 3, the horizontal axis includes a plurality of frequency bins, each bin corresponding to a discrete frequency in the spectrum as occurs when the Fourier transform is discretized through the Fast Fourier Transform (FFT) or discrete Fourier transform (DFT), as will be understood by those skilled in the art. In FIG. 3, random jitter is seen to be a relatively constant noise floor distributed relatively evenly among the spectral components of the spectrum (i.e., among the frequency bins). In contrast, the deterministic jitter DJ, which is shown as including periodic jitter PJ and data dependent jitter DDJ in FIG. 3, is seen as spikes or impulses rising above the relatively constant noise floor of the random jitter RJ in the TIE spectrum. This is true for other forms of deterministic jitter DJ as well, and allows the deterministic jitter to be picked out or identified in the TIE spectrum. In this way, the TIE spectrum enables the separation of deterministic jitter DJ and random jitter RJ.

The TIE spectrum of a sampled signal, such as shown in FIG. 3, is generated from a TIE time train as will be understood by those skilled the art, and thus the generation of the TIE time train is now only briefly described herein. The measurement of a time interval error (TIE) of a signal under test involves comparison of edge time locations in a sampled signal waveform with edge times in a calculated ideal signal waveform having no jitter. The TIE of a signal is found by calculating the difference in time between the threshold crossing of each edge in the sampled signal and the corresponding edge of the ideal signal waveform. The measurement of the TIE of a signal under test yields the TIE time train for the signal, where the TIE time train is a time domain signal embodying many aspects of the jitter, including the total jitter of the signal under test SUT. The determination of the TIE time train of a signal under test is described in more detail in U.S. Pat. No. 6,832,172 to Ward et al. titled “APPARATUS AND METHOD FOR SPECTRUM ANALYSIS-BASED SERIAL DATA JITTER MEASUREMENT,” ('172 patent) filed on May 16, 2002, the disclosure of which is incorporated herein by reference in its entirety.

Returning to the flowchart of FIG. 2, before the N-UI jitter analyzer 104 begins execution of the process 200, the test and measurement instrument 102 acquires a waveform of the signal under test DUT and the N-UI jitter analyzer 104 then in operation 202 the process 200 determines a TIE time train of the signal under test SUT. The process 200 thereafter goes from operation 202 to operation 204 in which the N-UI jitter analyzer 104 performs a Fourier transform, such as a Fast Fourier Transform (FFT) or Discrete Fourier Transform (DFT), on the TIE time train to generate the TIE spectrum of the TIE time train in operation 206. The TIE spectrum includes a plurality of frequency bins, each frequency bin containing a spectral component of the TIE spectrum. In some embodiments, the generation of the TIE time train and TIE spectrum for the signal under test SUT may be generated by other components in the test and measurement instrument 102, such as suitable instructions executing on the one or more processors 108 (FIG. 1), and provided to the N-UI jitter analyzer 104 for use in determining N-UI jitter of the signal under test.

Once the TIE spectrum of the signal under test SUT has been determined in operation 206, the process 200 proceeds to operation 208 and performs spectral impulse detection on the TIE spectrum to identify in operation 210 frequency bins in the TIE spectrum containing deterministic jitter DJ. As seen in FIG. 3, the TIE spectrum of a signal under test SUT enables deterministic jitter DJ of various forms to be identified in the form of spikes or impulses rising above the noise floor of the random jitter RJ in the TIE spectrum. The N-UI jitter analyzer 104 may utilize various approaches to separate the impulses of deterministic jitter DJ in the TIE spectrum from the noise floor of the random jitter RJ to identify frequency bins in the TIE spectrum containing deterministic jitter DJ. Suitable approaches are described in more detail in the '172 patent, which is incorporated herein by reference in its entirety. Once the process 200 has identified spectral locations (i.e., frequency bins) of the deterministic jitter DJ in the TIE spectrum in operation 210, the process proceeds to operation 212 and spectral separation of the N-UI spectrum of the signal under test SUT, which will be described in more detail below.

As seen in FIG. 2, once the TIE spectrum of the signal under test SUT is determined in operation 206, in addition to performing operations 208 and 210 as just discussed, the process 200 also includes operation 214 in which the N-UI jitter analyzer 104 performs scalloped filtering on the TIE spectrum to yield, in operation 216, the N-UI spectrum of the signal under test SUT, which will now be described in more detail. In embodiments of the N-UI jitter analyzer 104, the N-UI jitter analyzer derives or determines the N-UI spectrum for the signal under test SUT directly from the TIE spectrum through the scalloped filtering in operation 214. As mentioned above, this eliminates the need for computing multiple long measurement trends on the signal under test SUT and performing transforms (e.g., FFT, DFT) to generate the corresponding N-UI spectrums. This saves time and computational resources in the test and measurement instrument 102 containing the N-UI jitter analyzer 104. The scalloped filtering in operation 214 to generate the N-UI spectrum in operation 216 for the signal under test SUT may be understood based on the following observations:

The time-domain array of values representing N-UI jitter for a given N is traditionally computed directly from the array of edge (transition) times for a waveform:

$$N - {UI}_{i} = {edge}_{i} - {edge}_{i - N} \qquad EQN 1$$

However, if the TIE array has already been computed, these N-UI arrays, for any and all N, can be computed directly as follows:

$$N - {UI}_{i} = {TIE}_{i} - {TIE}_{i - N} + N * UI \qquad EQN 2$$

Furthermore, once the DFT of the TIE has been computed, the DFT of N-UI for any N can be directly computed based on linearity properties of the DFT. Suppose that we have the following DFT pairs, where the subscripts i and k refer to the time and frequency domain index variables respectively and [symbol] represents the (digital) Fourier Transform, so that:

$$TIE [ i ] {⇔}^{ℱ} TIE [ k ] \qquad EQN 3$$

$$N - UI [ i ] {⇔}^{ℱ} N - UI [ k ] \qquad EQN 4$$

And that we use a DFT of length K. Then EQN5 is:

$$N - UI [ k ] = ℱ 〈 N - UI [ i ] 〉 = ℱ ( TIE [ i ] - TIE [ i - N ] + N * UI )$$

The final term, N*UI, is a constant, for which the Fourier transform will only influence the bin corresponding to zero frequency. This component is not of interest for the purposes of jitter processing, and can therefore be dropped. We can then use a linearity property of the (digital) Fourier transform:

$$x [ i - Δ ] {⇔}^{ℱ} x [ k ] {e}^{- j \frac{2 π k Δ}{K}} \qquad EQN 6$$

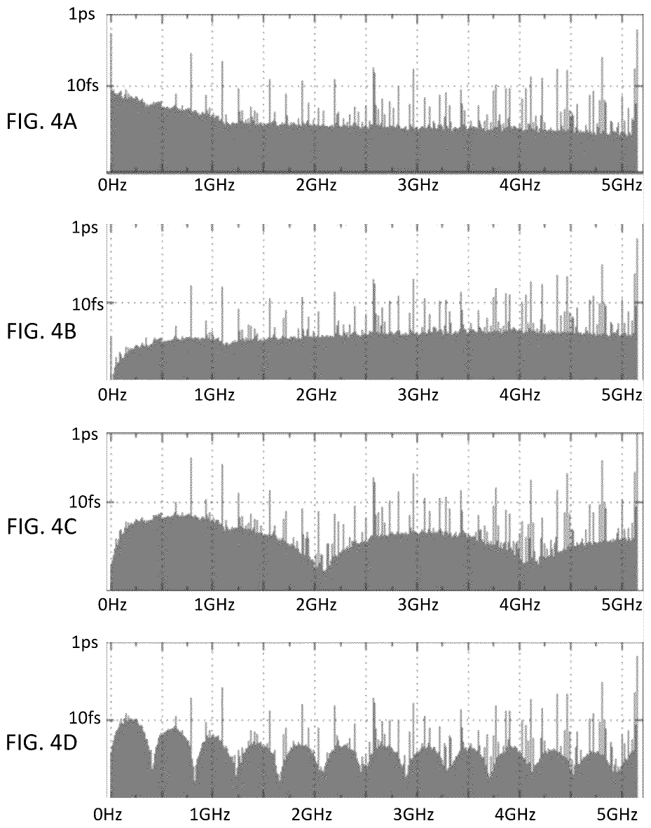

And arrive at the following:

$$N - UI [ k ] = TIE [ k ] ( 1 - {e}^{- j \frac{2 π k N}{K}} ) \qquad EQN 7$$

where N-UI[k] is the N-UI spectrum for the signal under test SUT, TIE[k] is the TIE spectrum, K is the length of the DFT or FFT for the TIE spectrum, k is a frequency index for the DFT or FFT, and N is the number of periods for the N-UI jitter measurements. The value of N may vary for a signal under test SUT, such as in the DDR5 SDRAM specification, which requires N-UI jitter measurements for the signal under test SUT for N=1 to 30. By using EQN 7, the N-UI jitter analyzer 104 may determine N-UI[k] (i.e., the N-UI spectrum) for different periods or values of N directly using the already determined TIE[k] (TIE spectrum) for the signal under test SUT. In EQN 7, it is the final term in parentheses that causes the scalloped shape of the noise floor of the N-UI spectrum as this exponential term successively passes through +1 and −1 as the value of N causes the phase to change. Thus, the operation of EQN 7, or more specifically the parenthetical term in EQN 7, as applied to the TIE spectrum is termed “scalloped filtering” in the present description. The scalloped nature or characteristics of the noise floor in the N-UI spectrum of a signal under test SUT will now be discussed in more detail with reference to FIGS. 4A-4D.

FIG. 4A shows an example TIE spectrum of a signal under test SUT, and is similar to the TIE spectrum of FIG. 3. FIGS. 4B-4D illustrate the N-UI spectrums for values of N=1, 5, and 25, respectively. The plots of FIGS. 4B-4D illustrate the scalloped nature of the noise floor of the random jitter RJ in the N-UI spectrum. The N-UI jitter spectrum differs from the TIE spectrum in that the N-UI spectrum has periodic nulls or dips in the noise floor of the spectrum. There is always a null at 0 Hz, and there are N nulls that are evenly spaced up to the clock or data rate, or N/2 nulls up to the Nyquist frequency. Because of the scalloped nature of the noise floors of these N-UI spectrums, the methods based on detecting spectral energy in the TIE spectrum to separate and determine components of total jitter, such as those described in the '172 patent, may not work well when measuring N-UI jitter due to the scalloped nature of the noise floor in the N-UI spectrum. The N-UI jitter analyzer 104 according to embodiments of the disclosure overcomes the problems of analyzing N-UI jitter resulting from this scalloped nature of the noise floor, which makes it difficult to distinguish spectral components of deterministic jitter DJ from spectral components of the random jitter RJ in the N-UI spectrum. As seen in the process 200 of FIG. 2, the N-UI jitter analyzer 104 overcomes these problems by first utilizing the TIE spectrum, which has a relatively flat noise floor for random jitter RJ as seen in FIG. 4A, to identify frequency bins containing deterministic jitter DJ instead of trying to identify these frequency bins directly in the N-UI spectrum. Once the N-UI jitter analyzer 104 has identified the frequency bins corresponding to deterministic jitter DJ in the TIE spectrum in operations 208 and 210 and the N-UI spectrum has been determined in operations 214 and 216, the process 200 switches to the N-UI spectrum for subsequent processing in operations 212-230, as will now be described in more detail with reference to FIG. 2.

In operations 212-230, the N-UI jitter analyzer 104 processes or analyzes the N-UI spectrum to determine the components of deterministic jitter DJ and characteristics of random jitter RJ of the N-UI-based jitter of the signal under test SUT. This analysis or processing includes filtering, inverse transforms to generate an N-UI time trains signal from the N-UI spectrum, histogram formation for each statistically independent deterministic jitter DJ component.

Once the individual components of deterministic jitter DJ and random jitter RJ are known, a bathtub curve can be derived. The bathtub curve allows extrapolation of the total jitter TJ and analysis of eye width versus bit error rate (BER) for the signal under test SUT, as will be understood by those skilled in the art and as described in more detail in the '172 patent. In embodiments of the disclosure, the processing of the N-UI spectrum by the N-UI jitter analyzer 104 corresponds to the processing performed on the TIE spectrum described in the '172 patent, except the N-UI jitter analyzer 104 performs this processing of the N-UI spectrum with frequency bins identified in operations 208 and 210 in the TIE spectrum.

Continuing now with the process 200 of FIG. 2, the process 200 in operation 212 begins analysis of the N-UI-based jitter of the signal under test SUT using the N-UI spectrum generated in operations 214 and 216. In operation 212, the process 200 performs adaptive spectral separation of the N-UI spectrum by generating an N-UI deterministic jitter DJ spectrum in operation 218 and generating an N-UI random jitter RJ spectrum in operation 220 for the signal under test SUT based on the identified frequency bins or deterministic jitter DJ spectral locations from operation 210 and the N-UI spectrum from operation 216. In operation 218, generating the N-UI deterministic jitter DJ spectrum may be determined by setting to zero all frequency bins in the N-UI spectrum except for frequency bins in the N-UI spectrum corresponding to the identified frequency bins in the TIE spectrum. From operation 218, the process 200 then goes to operation 222 and performs an inverse transform (IFFT or IDFT) on the N-UI DJ spectrum from operation 218 to generate a deterministic jitter DJ time train in operation 224. This deterministic jitter DJ time train may then be further analyzed to determine specific properties of deterministic jitter DJ. For example, the peak-to-peak value of DJ can be determined directly from the deterministic jitter DJ time train from operation 224. A histogram of the deterministic jitter DJ may be determined in an operation 226, as described in more detail in the '172 patent. Operations corresponding to the operations 222-226 are described in more detail in the '172 patent in relation to processing of the TIE spectrum of a signal under test SUT, with the operations being performed on the N-UI DJ spectrum in embodiments of the present disclosure.

Returning now to the spectral separation operation 212 in the process 200, the spectral separation operation further generates the N-UI random jitter spectrum of operation 220 by setting to zero all frequency bins in the N-UI spectrum corresponding to the identified frequency bins in the TIE spectrum as determined in in operation 210. After the N-UI random jitter RJ spectrum is determined in operation 220, the process proceeds to operations 228 and 230 to characterize the N-UI random jitter spectrum. More specifically, in operation 220 the process 200 determines a root-mean-square (RMS) value for the N-UI random jitter RJ spectrum and then in operation 230, records this RMS value as the standard deviation value for the N-UI random jitter RJ spectrum, which is assumed to be Gaussian as previously mentioned. As previously noted, the zero frequency bin of the Fourier transform (corresponding to the mean value of the jitter) is not of interest and was dropped, so the RMS and standard deviation are equivalent.

Aspects of the disclosure may operate on a particularly created hardware, on firmware, digital signal processors, or on a specially programmed general purpose computer including a processor operating according to programmed instructions. The terms controller or processor as used herein are intended to include microprocessors, microcomputers, Application Specific Integrated Circuits (ASICs), and dedicated hardware controllers. One or more aspects of the disclosure may be embodied in computer-usable data and computer-executable instructions, such as in one or more program modules, executed by one or more computers (including monitoring modules), or other devices. Generally, program modules include routines, programs, objects, components, data structures, etc. that perform particular tasks or implement particular abstract data types when executed by a processor in a computer or other device. The computer executable instructions may be stored on a non-transitory computer readable medium such as a hard disk, optical disk, removable storage media, solid state memory, Random Access Memory (RAM), etc. As will be appreciated by one of skill in the art, the functionality of the program modules may be combined or distributed as desired in various aspects. In addition, the functionality may be embodied in whole or in part in firmware or hardware equivalents such as integrated circuits, FPGA, and the like. Particular data structures may be used to more effectively implement one or more aspects of the disclosure, and such data structures are contemplated within the scope of computer executable instructions and computer-usable data described herein.

The disclosed aspects may be implemented, in some cases, in hardware, firmware, software, or any combination thereof. The disclosed aspects may also be implemented as instructions carried by or stored on one or more or non-transitory computer-readable media, which may be read and executed by one or more processors. Such instructions may be referred to as a computer program product. Computer-readable media, as discussed herein, means any media that can be accessed by a computing device. By way of example, and not limitation, computer-readable media may comprise computer storage media and communication media.

Computer storage media means any medium that can be used to store computer-readable information. By way of example, and not limitation, computer storage media may include RAM, ROM, Electrically Erasable Programmable Read-Only Memory (EEPROM), flash memory or other memory technology, Compact Disc Read Only Memory (CD-ROM), Digital Video Disc (DVD), or other optical disk storage, magnetic cassettes, magnetic tape, magnetic disk storage or other magnetic storage devices, and any other volatile or nonvolatile, removable or non-removable media implemented in any technology. Computer storage media excludes signals per se and transitory forms of signal transmission.

Communication media means any media that can be used for the communication of computer-readable information. By way of example, and not limitation, communication media may include coaxial cables, fiber-optic cables, air, or any other media suitable for the communication of electrical, optical, Radio Frequency (RF), infrared, acoustic or other types of signals.

Additionally, this written description makes reference to particular features. It is to be understood that the disclosure in this specification includes all possible combinations of those particular features. For example, where a particular feature is disclosed in the context of a particular aspect, that feature can also be used, to the extent possible, in the context of other aspects.

Also, when reference is made in this application to a method having two or more defined steps or operations, the defined steps or operations can be carried out in any order or simultaneously, unless the context excludes those possibilities.

Although specific aspects of the disclosure have been illustrated and described for purposes of illustration, it will be understood that various modifications may be made without departing from the spirit and scope of the disclosure.

### EXAMPLES

Illustrative examples of the technologies disclosed herein are provided below. A configuration of the technologies may include any one or more, and any combination of, the examples described below.

Example 1 is a method, including determining a time interval error (TIE) spectrum for a signal under test, the TIE spectrum including a plurality of frequency bins; identifying frequency bins in the TIE spectrum containing deterministic jitter; determining components of total jitter for the signal under test based on frequency bins in an N-UI spectrum for the signal under test corresponding to the identified frequency bins in the TIE spectrum.

Example 2 is the method of Example 1, further including determining, from the TIE spectrum, the N-UI spectrum for the signal under test.

Example 3 is the method of Example 2, wherein determining, from the TIE spectrum, the N-UI spectrum for the signal under test comprises determining the N-UI spectrum from the following equation:

$$N - UI [ k ] = TIE [ k ] ( 1 - {e}^{- j \frac{2 π k N}{K}} )$$

wherein N-UI[k] is the N-UI spectrum for the signal under test, TIE[k] is the TIE spectrum, K is the length of a transform for the TIE spectrum, k is a frequency index for the transform, and N is the number of periods for N-UI jitter measurements.

Example 4 is the method of Example 3, wherein multiple N-UI spectrums N-UI[k] are obtained, each for an N-UI spectrum corresponding to a different value of N, and wherein only one transform of the signal under test is performed to generate the TIE spectrum TIE[k].

Example 5 is the method of Example 1, wherein the signal under test comprises a clock signal.

Example 6 is the method of Example 1, wherein determining components of total jitter for the signal under test based on frequency bins in the N-UI spectrum for the signal under test corresponding to the identified frequency bins in the TIE spectrum further comprises performing adaptive spectral separation of the N-UI spectrum by generating an N-UI deterministic jitter spectrum and generating an N-UI random jitter spectrum for the signal under test based on the identified frequency bins and the N-UI spectrum.

Example 7 is the method of Example 6, wherein generating the N-UI deterministic jitter spectrum comprises setting to zero all frequency bins in the N-UI spectrum except for frequency bins in the N-UI spectrum corresponding to the identified frequency bins in the TIE spectrum.

Example 8 is the method of Example 7, further including performing an inverse Fourier transform on the N-UI deterministic jitter spectrum to generate an N-UI deterministic jitter time train.

Example 9 is the method of Example 6, wherein generating the N-UI random jitter spectrum comprises setting to zero all frequency bins in the N-UI spectrum corresponding to the identified frequency bins in the TIE spectrum.

Example 10 is the method of Example 9, further including characterizing the N-UI random jitter spectrum by determining a root-mean-square (RMS) value and standard deviation value for the N-UI random jitter spectrum.

Example 11 is a test and measurement instrument, including an N-UI jitter analyzer configured to receive an acquired waveform of a signal under test, the N-UI jitter analyzer configured to: determine a time interval error (TIE) spectrum of a signal under test, the TIE spectrum including a plurality of frequency bins; identify frequency bins in the TIE spectrum containing deterministic jitter in the signal under test; and determine components of total jitter for the signal under test based on frequency bins in an N-UI spectrum for the signal under test corresponding to the identified frequency bins in the TIE spectrum.

Example 12 is the test and measurement instrument of Example 11, wherein the N-UI jitter analyzer is further configured to determine, from the TIE spectrum, the N-UI spectrum of the signal under test.

Example 13 is the test and measurement instrument of Example 12, wherein to determine, from the TIE spectrum, the N-UI spectrum for the signal under test, the N-UI jitter analyzer is further configured to determine the N-UI spectrum from the following equation:

$$N - UI [ k ] = TIE [ k ] ( 1 - {e}^{- j \frac{2 π k N}{K}} )$$

wherein N-UI[k] is the N-UI spectrum for the signal under test, TIE[k] is the TIE spectrum, K is the length of a transform for the TIE spectrum, k is a frequency index for the transform, and N is the number of periods for N-UI jitter measurements.

Example 14 is test and measurement system, including a device under test configured to provide a signal under test; and a test and measurement instrument coupled to the device under test to receive the signal under test, the test and measurement instrument an N-UI jitter analyzer configured to: determine a time interval error (TIE) spectrum for the signal under test, the TIE spectrum including a plurality of frequency bins; derive, directly from the TIE spectrum, an N-UI spectrum for the signal under test; and perform adaptive spectral separation on the N-UI spectrum to determine components of total jitter for the signal under test.

Example 15 is the test and measurement system of Example 14, wherein to perform adaptive spectral separation the N-UI jitter analyzer is further configured to: identify frequency bins in the TIE spectrum containing deterministic jitter for the signal under test; and generate an N-UI deterministic jitter spectrum and an N-UI random jitter spectrum for the signal under test based on the identified frequency bins and the N-UI spectrum.

Example 16 is the test and measurement system of Example 15, wherein to generate the N-UI deterministic jitter spectrum the N-UI jitter analyzer is further configured to set to zero all frequency bins in the N-UI spectrum except for frequency bins in the N-UI spectrum corresponding to the identified frequency bins in the TIE spectrum.

Example 17 is the test and measurement system of Example 16, wherein to generate the N-UI random jitter spectrum the N-UI jitter analyzer is further configured to set to zero all frequency bins in the N-UI spectrum corresponding to the identified frequency bins in the TIE spectrum.

Example 18 is the test and measurement system of Example 15, wherein the test and measurement instrument comprises an oscilloscope.

Example 19 is the test and measurement system of Example 15, wherein the device under test comprises a Double Data Rate 5 Synchronous Dynamic Random Access Memory (DDR5 SDRAM) memory device.

Example 20 is the test and measurement system of Example 15, wherein to derive, directly from the TIE spectrum, the N-UI spectrum for the signal under test, the N-UI jitter analyzer is further configured to determine the N-UI spectrum from the following equation:

$$N - UI [ k ] = TIE [ k ] ( 1 - {e}^{- j \frac{2 π k N}{K}} )$$

wherein N-UI[k] is the N-UI spectrum for the signal under test, TIE[k] is the TIE spectrum, K is the length of a transform for the TIE spectrum, k is a frequency index for the transform, and N is the number of periods for N-UI jitter measurements.

The foregoing description has been set forth merely to illustrate example embodiments of disclosure and is not intended to be limiting. Since modifications of the disclosed embodiments incorporating the substance of the invention may occur to person skilled in the art, the invention should be construed to include everything within the scope of the invention.

The previously described versions of the disclosed subject matter have many advantages that were either described or would be apparent to a person of ordinary skill. Even so, these advantages or features are not required in all versions of the disclosed apparatus, systems, or methods.

Additionally, this written description makes reference to particular features. It is to be understood that all features disclosed in the specification, including the claims, abstract, and drawings, and all the steps in any method or process disclosed, may be combined in any combination, except combinations where at least some of such features and/or steps are mutually exclusive. Each feature disclosed in the specification, including the claims, abstract, and drawings, can be replaced by alternative features serving the same, equivalent, or similar purpose, unless expressly stated otherwise.

Also, when reference is made in this application to a method having two or more defined steps or operations, the defined steps or operations can be carried out in any order or simultaneously, unless the context excludes those possibilities.

Although specific examples of the disclosure have been illustrated and described for purposes of illustration, it will be understood that various modifications may be made without departing from the spirit and scope of the disclosure. Accordingly, the disclosure should not be limited except as by the appended claims.

We claim:

1. A method, comprising:
determining a time interval error (TIE) spectrum for a signal under test, the TIE spectrum including a plurality of frequency bins;
identifying frequency bins in the TIE spectrum containing deterministic jitter; and
determining components of total jitter for the signal under test based on frequency bins in an N-UI spectrum for the signal under test corresponding to the identified frequency bins in the TIE spectrum.

2. The method of claim 1, further comprising determining, from the TIE spectrum, the N-UI spectrum for the signal under test.

3. The method of claim 2, wherein determining, from the TIE spectrum, the N-UI spectrum for the signal under test comprises determining the N-UI spectrum from the following equation:
$$N - UI [ k ] = TIE [ k ] ( 1 - {e}^{- j \frac{2 π k N}{K}} )$$
wherein N-UI[k] is the N-UI spectrum for the signal under test, TIE[k] is the TIE spectrum, K is the length of a transform for the TIE spectrum, k is a frequency index for the transform, and N is the number of periods for N-UI jitter measurements.

4. The method of claim 3, wherein multiple N-UI spectrums N-UI[k] are obtained, each for an N-UI spectrum corresponding to a different value of N, and wherein only one transform of the signal under test is performed to generate the TIE spectrum TIE[k].

5. The method of claim 1, wherein the signal under test comprises a clock signal.

6. The method of claim 1, wherein determining components of total jitter for the signal under test based on frequency bins in the N-UI spectrum for the signal under test corresponding to the identified frequency bins in the TIE spectrum further comprises performing adaptive spectral separation of the N-UI spectrum by generating an N-UI deterministic jitter spectrum and generating an N-UI random jitter spectrum for the signal under test based on the identified frequency bins and the N-UI spectrum.

7. The method of claim 6, wherein generating the N-UI deterministic jitter spectrum comprises setting to zero all frequency bins in the N-UI spectrum except for frequency bins in the N-UI spectrum corresponding to the identified frequency bins in the TIE spectrum.

8. The method of claim 7, further comprising performing an inverse Fourier transform on the N-UI deterministic jitter spectrum to generate an N-UI deterministic jitter time train.

9. The method of claim 6, wherein generating the N-UI random jitter spectrum comprises setting to zero all frequency bins in the N-UI spectrum corresponding to the identified frequency bins in the TIE spectrum.

10. The method of claim 9, further comprising characterizing the N-UI random jitter spectrum by determining a root-mean-square (RMS) value and standard deviation value for the N-UI random jitter spectrum.

11. A test and measurement instrument, comprising:
an N-UI jitter analyzer configured to receive an acquired waveform of a signal under test, the N-UI jitter analyzer configured to:
determine a time interval error (TIE) spectrum of a signal under test, the TIE spectrum including a plurality of frequency bins;
identify frequency bins in the TIE spectrum containing deterministic jitter in the signal under test; and
determine components of total jitter for the signal under test based on frequency bins in an N-UI spectrum for the signal under test corresponding to the identified frequency bins in the TIE spectrum.

12. The test and measurement instrument of claim 11, wherein the N-UI jitter analyzer is further configured to determine, from the TIE spectrum, the N-UI spectrum of the signal under test.

13. The test and measurement instrument of claim 12, wherein to determine, from the TIE spectrum, the N-UI spectrum for the signal under test, the N-UI jitter analyzer is further configured to determine the N-UI spectrum from the following equation:
$$N - UI [ k ] = TIE [ k ] ( 1 - {e}^{- j \frac{2 π k N}{K}} )$$
wherein N-UI[k] is the N-UI spectrum for the signal under test, TIE[k] is the TIE spectrum, K is the length of a transform for the TIE spectrum, k is a frequency index for the transform, and N is the number of periods for N-UI jitter measurements.

14. A test and measurement system, comprising:
a device under test configured to provide a signal under test; and
a test and measurement instrument coupled to the device under test to receive the signal under test, the test and measurement instrument an N-UI jitter analyzer configured to:
determine a time interval error (TIE) spectrum for the signal under test, the TIE spectrum including a plurality of frequency bins;
derive, directly from the TIE spectrum, an N-UI spectrum for the signal under test; and
perform adaptive spectral separation on the N-UI spectrum to determine components of total jitter for the signal under test.

15. The test and measurement system of claim 14, wherein to perform adaptive spectral separation the N-UI jitter analyzer is further configured to:
identify frequency bins in the TIE spectrum containing deterministic jitter for the signal under test; and
generate an N-UI deterministic jitter spectrum and an N-UI random jitter spectrum for the signal under test based on the identified frequency bins and the N-UI spectrum.

16. The test and measurement instrument of claim 15, wherein to generate the N-UI deterministic jitter spectrum the N-UI jitter analyzer is further configured to set to zero all frequency bins in the N-UI spectrum except for frequency bins in the N-UI spectrum corresponding to the identified frequency bins in the TIE spectrum.

17. The test and measurement instrument of claim 16, wherein to generate the N-UI random jitter spectrum the N-UI jitter analyzer is further configured to set to zero all frequency bins in the N-UI spectrum corresponding to the identified frequency bins in the TIE spectrum.

18. The test and measurement system of claim 15, wherein the test and measurement instrument comprises an oscilloscope.

19. The test and measurement system of claim 15, wherein the device under test comprises a Double Data Rate 5 Synchronous Dynamic Random Access Memory (DDR5 SDRAM) memory device.

20. The test and measurement system of claim 15, wherein to derive, directly from the TIE spectrum, the N-UI spectrum for the signal under test, the N-UI jitter analyzer is further configured to determine the N-UI spectrum from the following equation:
$$N - UI [ k ] = TIE [ k ] ( 1 - {e}^{- j \frac{2 π k N}{K}} )$$
wherein N-UI[k] is the N-UI spectrum for the signal under test, TIE[k] is the TIE spectrum, K is the length of a transform for the TIE spectrum, k is a frequency index for the transform, and N is the number of periods for N-UI jitter measurements.
